(19) United States
(12) Patent Application Publication
(10) Pub. No.: US 2010/0071869 A1
(43) Pub. Date: Mar. 25, 2010

(54) COOLING SYSTEM

(75) Inventor: Noel William Lovisa, Townsville (AU)

Correspondence Address: DLA PIPER US LLP, 1999 AVENUE OF THE STARS, SUITE 400, LOS ANGELES, CA, 90067-6023, US

(73) Assignee: CODE VALLEY CORP PTY LTD, Townsville (AU)

(21) Appl. No.: 12/535,603

(22) Filed: Aug. 4, 2009

(30) Foreign Application Priority Data
Aug. 6, 2008 (AU) 2008904011

(51) Int. Cl. F25B 29/00; F24J 2/04; F03G 6/06; F03D 9/00; H05K 7/20

(52) U.S. Cl. 165/48.2; 126/634; 60/641.8; 290/55; 361/679.46

(57) ABSTRACT

Apparatus for cooling, the apparatus including a solar tower having a collector extending radially outwardly from a base of a chimney, the collector being for heating air at least in part using solar radiation to thereby induce air flow radially inwardly from a perimeter of the collector and up the chimney and at least one cooling air pipe, the cooling air pipe extending at least partially along a length of the chimney to allow cool air to be drawn through the pipe at least partially using the air flow, the cool air being used to provide cooling.

### CROSS-REFERENCE TO RELATED APPLICATIONS

This patent application claims priority to Australian Patent Application No. 2008904011, filed Aug. 6, 2008, incorporated by reference in its entirety.

### BACKGROUND OF THE INVENTION

1. Field of the Invention

The present invention relates to a method and apparatus for providing cooling, and in particular to a method and apparatus for providing cooling and electrical power to a number of computer systems.

2. Description of Related Art

The reference in this specification to any prior publication (or information derived from it), or to any matter which is known, is not, and should not be taken as an acknowledgment or admission or any form of suggestion that the prior publication (or information derived from it) or known matter forms part of me common general knowledge in the field of endeavor to which this specification relates.

A solar tower is a power station where turbines are mounted in a chimney to recover electrical energy from warm rising air which is heated by sunlight through a large translucent skin surrounding the chimney. Solar towers can readily store heat under the skirt to provide 24 hour operation. Such a technology is gaining momentum in recent times for its clean green environmentally friendly operation.

U.S. Pat. No. 4,275,309 describes a system for converting solar heat to electrical energy by accumulating normally non-heated air under a transparent roof which covers a vast area of sand, gravel, or rock covered ground. The accumulated air is sucked into a very high tower of large diameter which is centrally located on said roof, by the existing air pressure differential. A central pedestal located within the tower, at its base, supports an electrical generator which is powered by an impeller which is activated by the air rising in the tower. A pair of truncated cones joined at their truncated openings provide a reduced area within which the impeller is located in order to increase the air velocity at this point, and the air entering the impeller is previously caused to assure a rotary motion by angular air entrances in an enclosure around said pedestal.

“Design of Commercial Solar tower Systems—Utilization of Solar Induced Convective Flows for Power Generation” by Schlaich J, Bergermann R, Schiel W, Weinrebe G (2005) in Journal of Solar Energy Engineering 127 (1): 117-124 describes calculations for determining the dimensions such towers required. In one example, to produce an output of 200 MW, the solar tower would need a collector having a surface area of approximately 38 km² and a chimney of approximately 1 km in height. The term “server farm” is often used to refer to a collection of computer systems used by an entity to provide processing capabilities such as web hosting, e-commerce, access to proprietary software, or the like. Such server farms can often include thousands of processors and consequently require a large amount of electricity, not just to power the processors themselves, but also to operate cooling equipment required to maintain the processors at an operational temperature.

The operational requirements of such server farms are dominated by network bandwidth and power considerations based on the need to supply electricity to operate the computer systems as well as to provide required air-conditioning or the like, necessary to maintain the processors within normal operational temperature ranges. Consequently, server farm performance is often limited by cooling and electricity requirements, and for this reason, a critical design parameter is often the performance per watt that can be obtained.

### SUMMARY OF THE INVENTION

It is an object of the present invention to substantially overcome, or at least ameliorate, one or more disadvantages of existing arrangements.

In a first broad form the present invention provides apparatus for cooling, the apparatus including:

a) a solar tower having a collector extending radially outwardly from a base of a chimney, the collector being for heating air at least in part using solar radiation to thereby induce air flow radially inwardly from a perimeter of the collector and up the chimney; and,

b) at least one cooling air pipe, the cooling air pipe extending at least partially along a length of the chimney to allow cool air to be drawn through the pipe at least partially using the air flow, the cool air being used to provide cooling.

Typically the apparatus is used for cooling equipment.

Typically the apparatus includes a housing for housing the equipment, the housing being arranged to allow the air flow to induce a cooling air flow over the equipment to provide cooling.

Typically the housing includes an inlet and an outlet arranged to allow the air flow to draw air from the inlet to the outlet to thereby provide the cooling air flow.

Typically the inlet is coupled to the cooling air pipe to thereby draw cool air into the housing.

Typically the housing includes at least one cooling pipe extending from the inlet to the equipment to thereby supply cool air to the equipment.

Typically the outlet is coupled to the chimney to thereby air through the housing.

Typically the housing is provided near a base of the chimney.

Typically air is drawn through the housing at least in part using a venturi effect.

Typically the solar tower includes at least one turbine, the at least one turbine being driven by the air flow to generate electricity.

Typically the at least one turbine is positioned in the chimney.

Typically the apparatus includes a plurality of turbines circumferentially spaced apart around under the collector.

Typically the electricity is used to at least partially power the equipment.

Typically the cooling pipe is thermally insulated.

Typically the equipment includes a number of computer systems.

In a second broad form, the present invention provides a method of providing cooling, the method including:

a) using a solar tower having a collector extending radially outwardly from a base of a chimney to heat air using solar radiation to thereby induce air flow radially inwardly from a perimeter of the collector and up the chimney:

b) using a cooling air pipe extending at least partially up a length of the chimney to draw cool air through the pipe at least partially using the air flow; and,

c) using the cool air to provide cooling.

Typically the method is performed using the apparatus of the first broad form of the invention.

In a third broad form the present invention provides apparatus for cooling equipment, the apparatus including:

a) a solar tower having a collector extending radially outwardly from a base of a chimney, the collector being for heating air using solar radiation to thereby induce air flow radially inwardly from a perimeter of the collector and up the chimney; and,

b) a housing for the equipment, the housing being arranged to allow the air flow to induce a cooling air flow over the equipment to thereby cool the equipment.

Typically the apparatus includes, a cooling air pipe, the cooling air pipe extending at least partially up a length of the chimney to allow cool air to be drawn through the pipe at least partially using the air flow, the cool air being used to provide cooling to the equipment.

Typically the apparatus is apparatus according to the first broad form of the invention.

In a fourth broad form the present invention provides a method for cooling a number of computer systems, the method including:

a) using a solar tower having a collector extending radially outwardly from a base of a chimney to heat air using solar radiation to thereby induce air flow radially inwardly from a perimeter of the collector and up the chimney; and,

b) using the air flow to induce a cooling air flow in a housing for the number of computer systems to thereby cool the computer systems.

Typically the method is performed using the apparatus of the third broad form of the invention.

The above described and many other features and attendant advantages of the present invention will become better understood by reference to the following detailed description when taken in conjunction with the accompanying drawings.

### BRIEF DESCRIPTION OF THE DRAWINGS

An example of the present invention will now be described with reference to the accompanying drawings, in which:

FIG. 1A is a schematic side view of a first example of a solar tower for providing cooling;

FIG. 1B is a schematic plan view of the cooling system of FIG. 1A;

FIG. 2A is a schematic side view of a second example of cooling system;

FIG. 2B is a schematic plan view of the cooling system of FIG. 2A;

FIG. 3A is a schematic side view of a first example of a cooling system for cooling a number of computer systems;

FIG. 3B is a schematic side view of a second example of a cooling system for cooling a number of computer systems;

FIG. 4A is a schematic side view of a third example of cooling system; FIG. 4B is a schematic plan view of the cooling system of FIG. 4A;

FIG. 5A is a schematic side view of a fourth example of cooling system; and,

FIG. 5B is a schematic plan view of the cooling system of FIG. 5A.

### DETAILED DESCRIPTION OF THE INVENTION

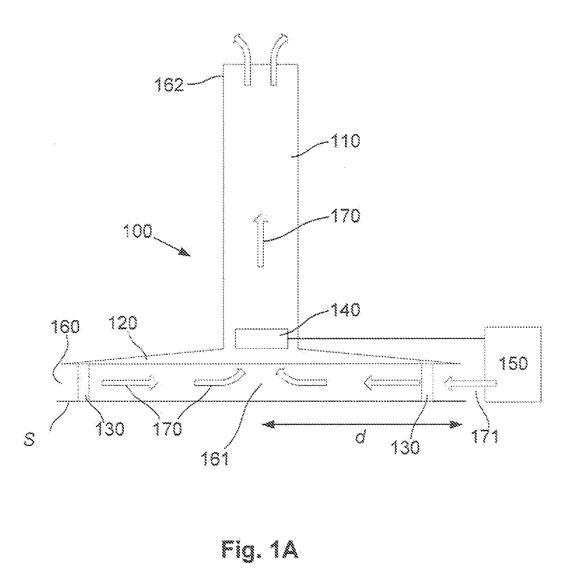

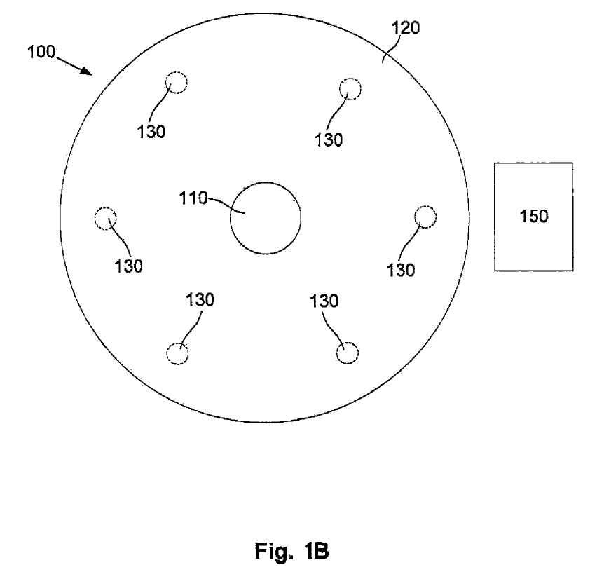

An example of apparatus for providing cooling will now be described with reference to FIGS. 1A and 1B.

In this example the apparatus includes a solar tower 100 having a chimney 110 and a solar collector 120 extending generally radially outwardly from a base 161 of the chimney 110. In general the chimney 110 and collector 120 are positioned above a surface S in use by a number of supports 130. Although six supports are shown, this is for the purpose of example only and it will be appreciated that in practice a larger number of supports would typically be used.

The apparatus may optionally include a generator 140, such as a turbine or the like, for generating electricity. The electricity may optionally be used to power apparatus or equipment shown generally at 150.

In use, solar radiation incident on the collector 120 is used to heat air positioned between the collector 120 and surface S. It will therefore be appreciated that the collector 120 is generally formed from a material that is transmissive to a solar radiation. Typically the collector 120 also needs to have a large surface area (in the case of a 200 MW capacity generating facility up to 38 km²) and the collector is therefore typically formed from a material that is cheap, lightweight and durable, as well as being transmissive. Accordingly, the collector is typically formed from a material such as plastic, glass, or the like.

In contrast to this, the chimney 110 need not be transmissive to solar radiation. Furthermore, given that the chimney typically needs to be of a significant height (in the case of a 200 MW capacity generating facility up to 1 km), it is therefore preferably formed from a cheap durable and strong material, such as concrete or the like.

In use, heating of air under the collector 120 causes a temperature differential between a collector perimeter 160, and the chimney base 161. In this instance, the temperature at the collector perimeter 160, which is substantially equal to a surface level ambient air temperature, is therefore significantly lower than the temperature at the chimney base 161.

In addition to this, there is also a temperature differential between the chimney base 161 and a chimney top 162, with the temperature at the chimney top 162 being significantly lower than both the temperature at the chimney base 161 and at the collector perimeter 160, due to the altitude of the chimney top 162.

The temperature differentials cause convection currents which in turn induce airflow from the collector perimeter 160 towards the chimney base 161 and then up the chimney 110, as shown by the arrows at 170. It will be appreciated that in use the airflow can be used to drive the turbine 140 and hence to generate electricity.

In addition to this, apparatus or equipment to be cooled, such as a number of computer systems, can be arranged so as to allow the airflow through the chimney to provide a cooling effect. In one example, the equipment is provided in an equipment housing 150 positioned adjacent the collector perimeter 160, so that airflow through the solar tower first passes through the equipment housing 150, as shown generally at 171. This allows the solar tower to provide cooling to the computer systems, or other equipment provided in the equipment housing 150.

Accordingly, it will be appreciated that the above described arrangement allows a solar updraft tower to be used to provide both cooling and power to a server farm, or other similar equipment. This has a number of benefits, including that most, if not all, server farm power requirements are met using a low emission renewable power source, and that overall power requirements are substantially reduced by avoiding the need to power additional cooling equipment.

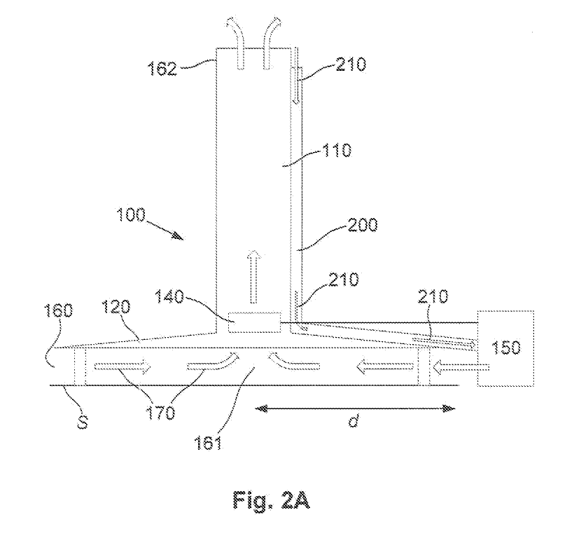

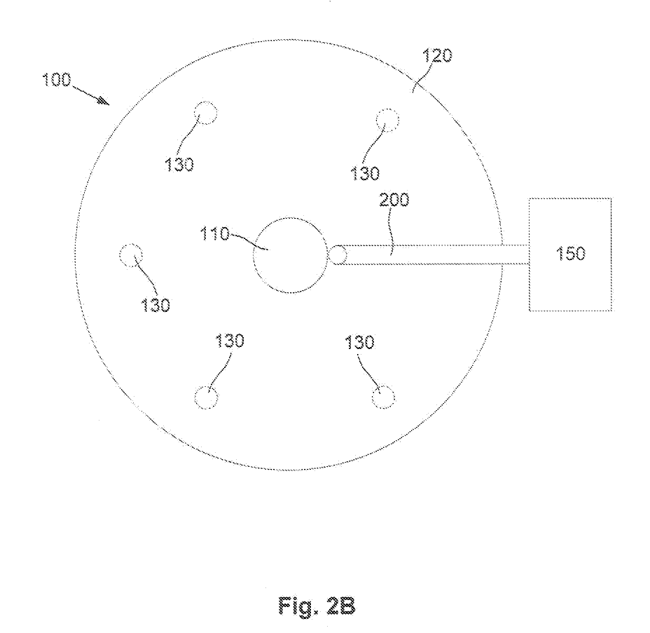

In one example, the air flowing through the equipment housing 150 is formed from air surrounding the solar collector 120 and is therefore generally at an ambient air temperature. At ground level, this can therefore be a temperature of up to 40° C., depending on the environment. Even an airflow at this temperature can provide cooling to hot equipment if the equipment is at a higher temperature. However, improved cooling can be achieved using chilled air. Whilst this can be provided in any manner, this can advantageously be achieved using the solar tower, as will now be described with reference to FIGS. 2A and 2B.

In this example, the solar tower is modified to include a cooling air pipe 200 that extends at least partially up the length of the chimney 110, and preferably to near the chimney top 102. The cooling air pipe 200 is used to allow cool air to be drawn into the cooling air pipe 200 from near the top 162 of the chimney 110, as shown by the arrows 210. It will be appreciated that the ambient air temperature at altitudes near the chimney top 162 is typically a few degrees cooler than the ambient air temperature at ground level, thereby allowing enhanced cooling to be provided. Typically the ambient temperature at a height (H) is governed by the equation:

t_{H}(° C.)=15−6.5×10⁻³ H(m)

In one example, the cooling air pipe 200 is thermally insulated in some manner to reduce heating of the air as it is transported to ground level. This can be achieved in any suitable manner such as making the cooling air pipe 200 from a suitable material, such as a material having a low thermal conductivity. Further alternatives are to place the cooling air pipe 200 on a shaded side of the chimney (e.g., on the northern side in the northern hemisphere and on the southern side in the southern hemisphere), to thereby shade the cooling pipe 200 from solar radiation, and/or to provide a suitable form of thermal insulation on the pipe.

Cool air can be drawn into the cooling air pipe 200 using any appropriate technique. However, in one preferred example this is achieved at least in part utilizing the airflow 171, for example by using a suitable housing for the equipment 150 and/or through the use of suitable ducting. In this regard, movement of warm air at the base of the tower is used to create a venturi effect. This results in a partial vacuum, which draws air in from the equipment 150, in turn causing cooler air to be drawn into the equipment, thereby providing the required cooling of equipment.

As mentioned above, the equipment can be any form of equipment. In one example, the system is used to provide cooling to a server farm, which is the term used to describe a collection of computing systems providing a data processing capability.

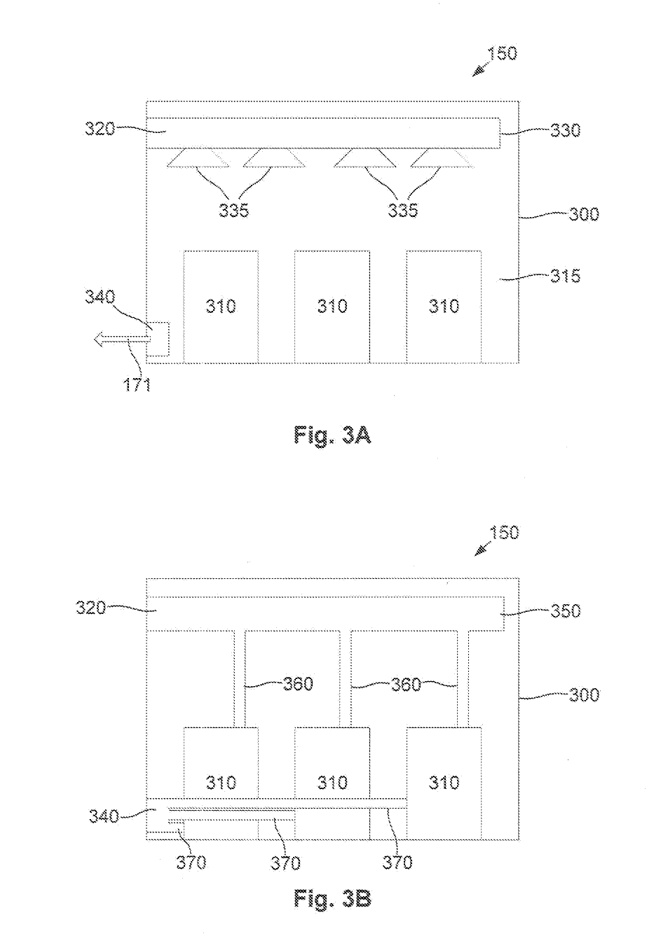

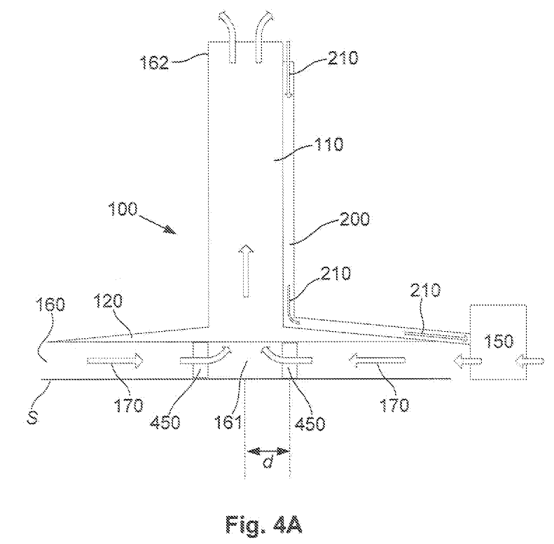

Specific examples in which the equipment includes a number of computer systems will now be described in more detail with respect to FIGS. 3A and 3B.

In the first example of FIG. 3A, a building 300 is provided containing a number of computer systems in a suitable housing as shown generally at 310. The computer systems may be of any suitable form, such as personal computers, a server rack, or the like. The building 300 includes an inlet 320, and an outlet 340 coupled to a distribution pipe 330 having a number of distribution outlets 335.

In this example, air is drawn out of the building through the outlet 340 as shown by the arrow 171. This in turn leads to air being drawn in through the inlet 320, thereby providing airflow through the building 300, with air exiting via the distribution outlets 335, and the distribution pipe 330.

It will be appreciated that this arrangement may be utilized with either of the arrangements of FIGS. 1A and 1B to provide airflow. Alternatively, it could be used with the arrangement of FIGS. 2A and 2B, allowing the inlet 320 to be coupled to the cooling pipe 200 to allow cool air to be supplied from the top of the chimney 162.

A second example is shown in FIG. 3B. In this arrangement, the outlet 340 is coupled to a distribution pipe 350 having a number of connecting pipes 360 coupled thereto. The connecting pipes 360 extend to the computer system housings 310. Similarly, the inlet 320 includes a number of connecting pipes 370 also coupled to the computer system housings 310.

Again, this arrangement allows air to be drawn in through the inlet 320, with the airflow passing through the connecting pipes 370 directly into the computer system housings. Thus, for example, if the computer systems 310 are in the form of server racks, each server rack can be provided with respective connecting pipes 370, allowing airflow to be provided directly into the server rack housings. This therefore ensures that adequate airflow is maintained over the computer equipment itself and not just within the building 300. Air with then be removed via the connecting pipes 360, the distribution pipe 350 and the outlet 340.

In the above described examples, cool air is shown being drawn into the building 300 via an inlet 320 provided near floor level, with warm air being removed via an outlet at ceiling level. However, this is not essential, and any suitable arrangement may be used.

It will be appreciated that the examples of equipment arrangements are for the purpose of illustration and any one of a number of different mechanisms can be used for drawing air into the housing 150. This can include, for example, utilizing a venturi effect in which the air flow and a suitable ducting or vent arrangement is used to generate a partial vacuum at the base of the tower. This in turn draws air through the building 300 and/or the computer system housings 310, thereby providing a mechanism to generate a flow of unhealed air for the purposes of cooling.

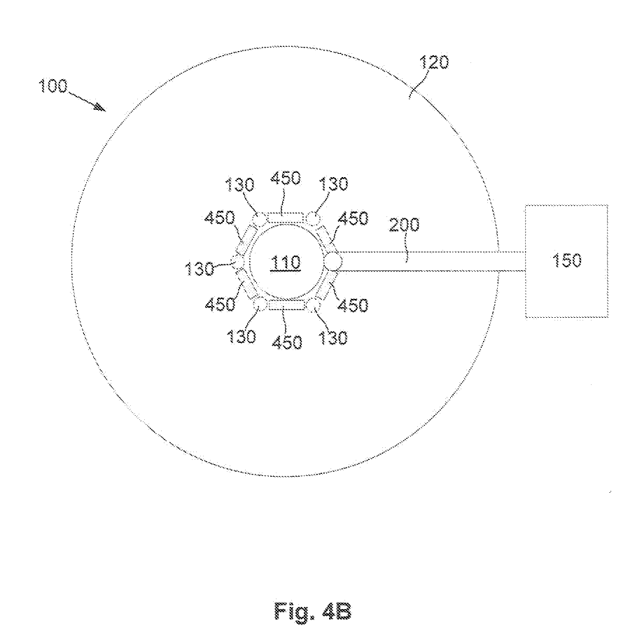

A third example of a solar tower will now be described with reference to FIGS. 4A and 4B. In this instance, the solar tower includes a number of turbines 450 positioned circumferentially around the solar tower under the collector 120. The turbines 450 may be provided at any radial position between the base of the chimney 161 and the perimeter 160 of the collector 110, as will be appreciated by persons skilled in the art.

In general however, air flow speed is greater towards the centre of the collector 120, and accordingly, it is preferable to arrange the turbines 450 toward the centre of the collector 120, as near to the chimney as possible, thereby minimizing the distance d between the turbines 140 and the centre of the chimney 110.

The single turbine arrangement shown in FIGS. 1 and 2, in which the turbine 140 is mounted horizontally within the chimney 110 is generally preferred for smaller solar towers, whilst the multiple turbine arrangement shown in FIG. 4, in which the turbines are mounted vertically under the collector 120, is generally preferred for larger towers. However, it will be appreciated that any suitable arrangement may be used.

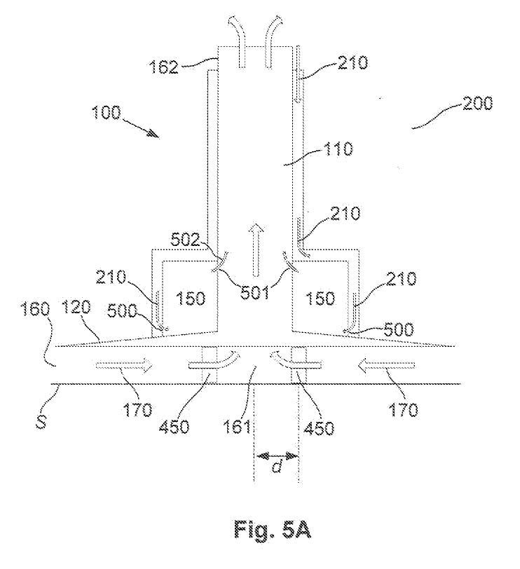

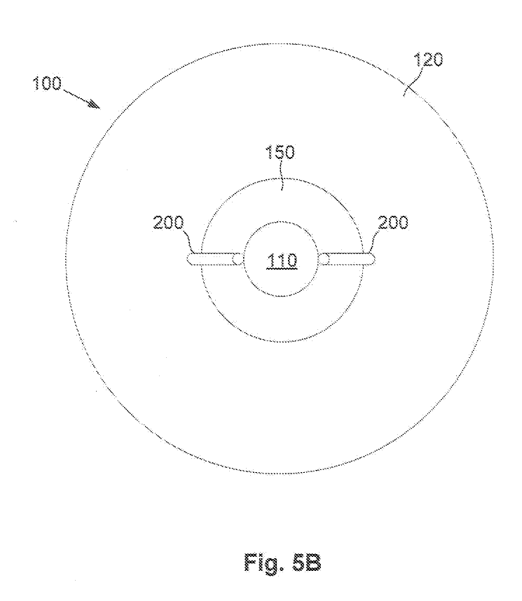

A fourth example of a solar tower will now be described with reference to FIGS. 5A and 5B. In this example, the equipment is positioned adjacent to, or otherwise near, the base of the chimney 110, to thereby provide enhanced cooling.

In this example, the equipment housing 150 is an annular housing extending around the chimney 110, just above the collector 120. Whilst an annular housing is shown, this is not essential and the equipment housing 150 could extend partially around, or simply be provided near the base of the chimney 120.

In this example, the equipment housing 150 includes an inlet 500, coupled to the cooling air pipe 200, allowing cool air to be received from the top of the chimney 120, as shown by the arrows 210. The equipment housing 150 also includes an outlet 501, allowing warmed air to be returned to the chimney 120, as shown at 502.

Positioning the equipment housing 150 near the base of the chimney reduces the distance over which cool air needs to be transported, thereby reducing any heating of the chilled air that occurs prior to the chilled air being supplied to the equipment 150. Additionally, this allows the heated air to be vented directly into the chimney 110. As air flow is also greatest close to the chimney base 161, high air flow rates near the outlet 501 ensure a strong venturi effect, which in turn maximizes air flow through the equipment housing 150.

Thus, it will be appreciated that arranging the equipment near to the base of the chimney 110 can provide an enhanced cooling effect. In practical terms, this can also allow the equipment housing 150 to form an integrated part of the chimney base 161, thereby minimizing the construction required to provide both the solar tower, and the equipment housing 150.

As also shown, in this example, multiple cooling pipes 200 can be provided to maximize the volume of cool air drawn into the equipment housing 15. Whilst two cooling pipes 200 are shown, this is for the purpose of example only, and in practice any number of cooling pipes 200 could be utilized.

It will be appreciated from the above that a number of different arrangements can be used and in particular a number of different turbine positions, collector and chimney arrangements, and the above examples are for the purpose of illustration only. It will be appreciated that a number of additional features may be utilized to further improve operation.

In one example, mechanisms may be provided for storing heat, so that air between the collector 120 and the surface S will be heated during times when incident solar radiation is insufficient to provide heating, such as at night. This may be achieved, for example, by providing material with a high specific heat capacity, such as water, so this can be heated during the day while solar radiation is present, with the heat being released at night, to allow continued operation of the updraft tower.

In one example, it is possible to employ multiple turbines for redundancy, so that if any one turbine fails, electricity supply remains operational.

Solar towers are generally proposed for use in supplying electricity to multiple customers. However, in one example, the solar tower is only used to supply power to a single priority customer in the form of the equipment operator, allowing improved control over the loads attached to the system. This has a number of benefits. For example, this allows operation of the equipment to be controlled to match the power generating capability of the tower, thereby reducing the likelihood of overloads.

Despite the reliability however, a backup connection to an alternative electricity supply, such as the mains supply, may be provided in case of failure or under supply from the solar tower. It will be appreciated that this represents an improvement over existing server farm arrangements, which rely on the grid as a primary power source, with diesel backup providing a secondary source, which therefore represents a significantly more expensive back-up option than the use of grid electricity supplies.

In addition, by providing connectivity to the electricity supply, green electrical energy can be exported to the power grid for a premium return, during periods of low server farm utilization.

Furthermore, the above described arrangements can obviate the need for moving parts. In particular, this allows CPU, mother board and room fans to be eliminated. As up to 20% of direct server power is consumed by the operation of the CPU and mother board fans alone, this can lead to a reduction in power requirements. Thus, eliminating the fans significantly improves efficiency and reliability while eliminating the air conditioning plant reduces capital cost and almost halves the electrical requirements.

It will be appreciated from the above that the solar tower can be used as a reliable source of electrical power, as well as to provide airflow of a significant velocity and optionally access to cool air. These commodities are ideal for use with a server farm as it can obviate the need for separate power sources and cooling capabilities.

In one example, this is achieved by using the solar tower to convert warm air under the collector, to kinetic energy, in the form of an air flow, by exploiting a temperature difference between the cooler top of the tower and the warmer base. This air flow can then be used to provide cooling to equipment, such as the server farm computer systems, as well as allowing electricity generation to power the server farm.

In addition to this, by exploiting the height of the tower, this allows cooler air to be drawn from altitude than that available at ground level. This cool air can be funneled down to the base with some suitably insulated ducting, and then directed over the servers to provide the necessary cooling. The resulting warmed air can then be expelled into the base of the tower for additional energy recovery by the chimney.

Thus, a solar tower virtually eliminates the need for uninterruptible power plant and equipment and its associated electrical energy burden and capital cost. This is in contrast to the use of conventional power supplies to server farms, which typically require power in the form of backup diesel generators and uninterruptible power supplies, as well as requiring power for operating cooling systems, such as air conditioning, thereby making their operation significantly more expensive. Using a solar tower for the purposes of operating a server farm therefore permits tighter controls over the reliability of the electricity supply, and reduces operating costs.

Having thus described exemplary embodiments of the present invention, it should be noted by those skilled in the art that the within disclosures are exemplary only and that various other alternatives, adaptations and modifications may be made within the scope of the present invention. Accordingly, the present invention is not limited to the above preferred embodiments and examples, but is only limited by the following claims.

What is claimed is:

1. Apparatus for cooling, the apparatus including:
a) a solar tower having a collector extending radially outwardly from a base of a chimney, the collector being for heating air at least in part using solar radiation to thereby induce air flow radially inwardly from a perimeter of the collector and up the chimney; and,
b) at least one cooling air pipe, the cooling air pipe extending at least partially along a length of the chimney to allow cool air to be drawn through the pipe at least partially using the air flow, the cool air being used to provide cooling.

2. Apparatus according to claim 1, wherein the apparatus is used for cooling equipment.

3. Apparatus according to claim 1, wherein the apparatus includes a housing for housing the equipment, the housing being arranged to allow the air flow to induce a cooling air flow over the equipment to provide cooling.

4. Apparatus according to claim 3, wherein the housing includes an inlet and an outlet arranged to allow the air flow to draw air from the inlet to the outlet to thereby provide the cooling air flow.

5. Apparatus according to claim 4, wherein the inlet is coupled to the cooling air pipe to thereby draw cool air into the housing.

6. Apparatus according to claim 5, wherein the housing includes at least one cooling pipe extending from the inlet to the equipment to thereby supply cool air to the equipment.

7. Apparatus according to claim 4, wherein the outlet is coupled to the chimney to thereby draw air through the housing.

8. Apparatus according to claim 3, wherein the housing is provided near a base of the chimney.

9. Apparatus according to claim 3, wherein air is drawn through the housing at least in part using a venturi effect.

10. Apparatus according to claim 1, wherein the solar tower includes at least one turbine, the at least one turbine being driven by the air flow to generate electricity.

11. Apparatus according to claim 10, wherein the at least one turbine is positioned in the chimney.

12. Apparatus according to claim 10, wherein the apparatus includes a plurality of turbines circumferentially spaced apart around under the collector.

13. Apparatus according to claim 1, wherein the electricity is used to at least partially power the equipment.

14. Apparatus according to claim 1, wherein the cooling pipe is thermally insulated.

15. Apparatus according to claim 1, wherein the equipment includes a number of computer systems.

16. A method of providing cooling, the method including:
a) using a solar tower having a collector extending radially outwardly from a base of a chimney to heat air using solar radiation to thereby induce air flow radially inwardly from a perimeter of the collector and up the chimney;
b) using a cooling air pipe extending at least partially up a length of the chimney to draw cool air through the pipe at least partially using the air flow; and,
c) using the cool air to provide cooling.

17. A method according to claim 16, wherein the method is performed using apparatus including:
a) a solar tower having a collector extending radially outwardly from a base of a chimney, the collector being for heating air at least in part using solar radiation to thereby induce air flow radially inwardly from a perimeter of the collector and up the chimney; and,
b) at least one cooling air pipe, the cooling air pipe extending at least partially along a length of the chimney to allow cool air to be drawn through the pipe at least partially using the air flow, the cool air being used to provide cooling.

18. Apparatus for cooling equipment, the apparatus including;
a) a solar tower having a collector extending radially outwardly from a base of a chimney, the collector being for heating air using solar radiation to thereby induce air flow radially inwardly from a perimeter of the collector and up the chimney; and,
b) a housing for the equipment, the housing being arranged to allow the air flow to induce a cooling air flow over the equipment to thereby cool the equipment.

19. Apparatus according to claim 18, wherein the apparatus includes, a cooling air pipe, the cooling air pipe extending at least partially up a length of the chimney to allow cool air to be drawn through the pipe at least partially using the air flow, the cool air being used to provide cooling to the equipment.

20. Apparatus according to claim 19, wherein, the apparatus includes:
a) a solar tower having a collector extending radially outwardly from a base of a chimney, the collector being for heating air at least in part using solar radiation to thereby induce air flow radially inwardly from a perimeter off the collector and up the chimney: and,
b) at least one cooling air pipe, the cooling air pipe extending at least partially along a length of the chimney to allow cool air to be drawn through the pipe at least partially using the air flow, the cool air being used to provide cooling.

21. A method for cooling a number of computer systems, the method including:
a) using a solar tower having a collector extending radially outwardly from a base of a chimney to heat air using solar radiation to thereby induce air flow radially inwardly from a perimeter of the collector and up the chimney; and,
b) using the air flow to induce a cooling air flow in a housing for the number of computer systems to thereby cool the computer systems.

22. A method according to claim 21, wherein the method is performed using apparatus including:
a) a solar tower having a collector extending radially outwardly from a base of a chimney, the collector being for heating air using solar radiation to thereby induce air flow radially inwardly from a perimeter of the collector and up the chimney; and,
b) a housing for the equipment, the housing being arranged to allow the air flow to induce a cooling air flow over the equipment to thereby cool the equipment.
